(19) United States
(12) Patent Application Publication
(10) Pub. No.: US 2025/0244819 A1
(43) Pub. Date: Jul. 31, 2025

(54) ENHANCED CURRENT LIMITING TECHNIQUES

(71) Applicant: QUALCOMM Incorporated, San Diego, CA (US)

(72) Inventor: Chris ROSOLOWSKI, Encinitas, CA (US)

(21) Appl. No.: 18/427,959

(22) Filed: Jan. 31, 2024

(51) Int. Cl. G06F 1/3296; G01R 19/165; G06F 1/3234

(52) U.S. Cl. CPC G06F 1/3296; G01R 19/16552; G06F 1/3243

(57) ABSTRACT

Certain aspects of the present disclosure are directed towards techniques and apparatus for power control. An example apparatus generally includes: a system on chip (SoC) having a plurality of processing units, wherein the plurality of processing units are coupled to respective voltage supply paths; voltage detection circuits coupled to the voltage supply paths and configured to detect voltages at the voltage supply paths, respectively; and a controller configured to control a power consumption of one or more of the plurality of processing units based on at least one of the detected voltages.

### TECHNICAL FIELD

Certain aspects of the present disclosure generally relate to electronic circuits and, more particularly, to techniques for current limiting for an electronic device.

### BACKGROUND

A voltage regulator may provide a constant direct current (DC) output voltage regardless of changes in load current or input voltage. Voltage regulators may be classified as linear regulators or switching regulators. While linear regulators tend to be relatively compact, many applications may benefit from the increased efficiency of a switching regulator. A linear regulator may be implemented by a low-dropout (LDO) regulator, for example. A switching regulator (also known as a “switching converter” or “switcher”) may be implemented, for example, by a switched-mode power supply (SMPS), such as a buck converter, a boost converter, a buck-boost converter, or a charge pump.

For example, a buck converter is a type of SMPS that may include: (1) a high-side switch coupled between a relatively higher voltage rail and a switching node, (2) a low-side switch coupled between the switching node and a relatively lower voltage rail, (3) and an inductor coupled between the switching node and a load. The high-side and low-side switches are typically implemented with transistors, although the low-side switch may alternatively be implemented with a diode.

Power management integrated circuits (power management ICs or PMICs) are used for managing the power scheme of a host system and may include and/or control one or more voltage regulators (e.g., buck converters and/or LDOs). A PMIC may be used in battery-operated devices, such as mobile phones, tablets, laptops, wearables, etc., to control the flow and direction of electrical power in the devices. The PMIC may perform a variety of functions for the device, such as DC-to-DC conversion (e.g., using a voltage regulator as described above), battery charging, power-source selection, voltage scaling, power sequencing, etc.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects of the present disclosure are directed towards an apparatus for power control. The apparatus generally includes: a system on chip (SoC) having a plurality of processing units, wherein the plurality of processing units are coupled to respective voltage supply paths; voltage detection circuits coupled to the voltage supply paths and configured to detect voltages at the voltage supply paths, respectively; and a controller configured to control a power consumption of one or more of the plurality of processing units based on at least one of the detected voltages.

Certain aspects of the present disclosure are directed towards an apparatus for power control. The apparatus generally includes: a plurality of processing units comprising respective voltage supply paths; voltage detection circuits coupled to the voltage supply paths and configured to detect a plurality of voltages at the voltage supply paths, respectively; and a controller configured to control a power consumption of one or more of the plurality of processing units based on the plurality of voltages.

Certain aspects of the present disclosure are directed towards a method for power control. The method generally includes: detecting voltages at voltage supply paths coupled to a plurality of processing units of a SoC; and controlling a power consumption of one or more of the plurality of processing units based on at least one of the detected voltages.

Certain aspects of the present disclosure are directed towards a method for power control. The method generally includes: detecting a plurality of voltages at voltage supply paths coupled to a plurality of processing units; and controlling a power consumption of one or more of the plurality of processing units based on the plurality of voltages.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a block diagram of an example device that includes a power supply system with at least one switched-mode power supply (SMPS) circuit, in which aspects of the present disclosure may be practiced.

FIG. 2 illustrates an electronic device including power management integrated circuits (PMICs) for different processing units, in accordance with certain aspects of the present disclosure.

FIG. 3 illustrates a graph showing the current consumption of a processing unit and a graph showing the voltage droop of the processing unit.

FIG. 4 illustrates graphs showing current consumption and supply voltage measurements associated with processing units, in accordance with certain aspects of the present disclosure.

FIGS. 5 and 6 are flow diagrams illustrating example operations for power supply control, in accordance with certain aspects of the present disclosure.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

Certain aspects of the present disclosure provide techniques and apparatus for current liming for an electronic device. For example, voltages may be sensed at the voltage supply paths for a chipset, including multiple processing units (e.g., processing cores). If at least one of the sensed voltages drops below some threshold (e.g., causing a voltage droop alarm), one or more of the processing units may be throttled (e.g., the current consumption of one or more processing units may be reduced) in an attempt to avoid a device crash. Certain aspects use multiple voltage droop alarms based on voltage measurements. Multiple droop alarms allow for coordination of throttling of (e.g., setting of peak current limits for) one or more processing units, determination of which processing units are to be throttled, and determination of the amount of throttling to be implemented, improving overall performance.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Device

It should be understood that aspects of the present disclosure may be used in a variety of applications. Although the present disclosure is not limited in this respect, the circuits disclosed herein may be used in any of various suitable apparatuses, such as in the power supply, battery charging circuit, or power management circuit of a communication system, a video codec, audio equipment such as music players and microphones, a television, camera equipment, and test equipment such as an oscilloscope. Communication systems intended to be included within the scope of the present disclosure include, by way of example only, cellular radiotelephone communication systems, satellite communication systems, two-way radio communication systems, one-way pagers, two-way pagers, personal communication systems (PCS), personal digital assistants (PDAs), and the like.

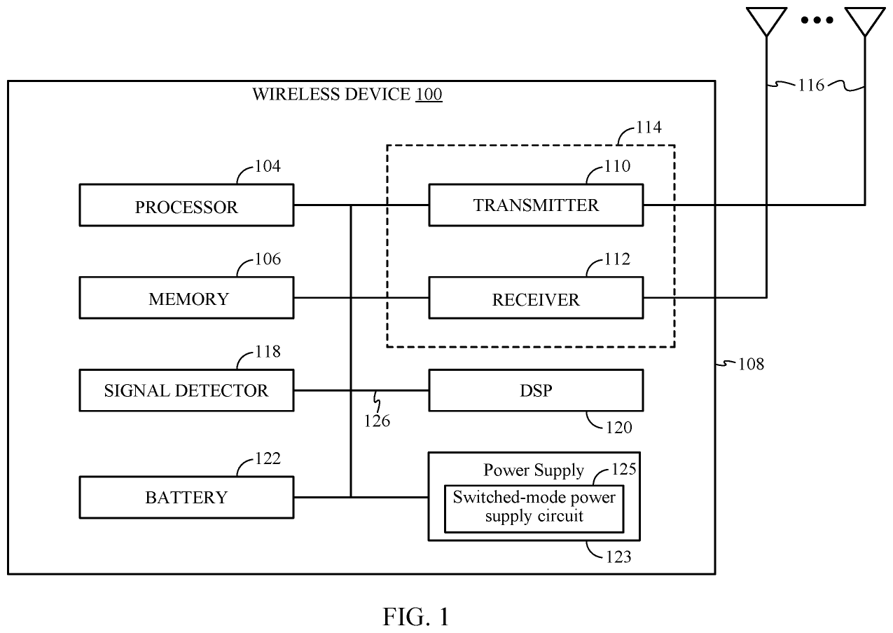

FIG. 1 illustrates an example device 100 in which aspects of the present disclosure may be implemented. The device 100 may be a battery-operated device such as a cellular phone, a PDA, a handheld device, a wireless device, a laptop computer, a tablet, a smartphone, an Internet of things (IoT) device, a wearable device, a virtual reality (VR) or augmented reality (AR) device, etc.

The device 100 may include a processor 104 that controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM). The processor 104 typically performs logical and arithmetic operations based on program instructions stored within the memory 106.

In certain aspects, the device 100 may also include a housing 108 that may include a transmitter 110 and a receiver 112 to allow transmission and reception of data between the device 100 and a remote location. For certain aspects, the transmitter 110 and receiver 112 may be combined into a transceiver 114. One or more antennas 116 may be attached or otherwise coupled to the housing 108 and electrically connected to the transceiver 114. The device 100 may also include (not shown) multiple transmitters, multiple receivers, and/or multiple transceivers.

The device 100 may also include a signal detector 118 that may be used in an effort to detect and quantify the level of signals received by the transceiver 114. The signal detector 118 may detect such signal parameters as total energy, energy per subcarrier per symbol, and power spectral density, among others. The device 100 may also include a digital signal processor (DSP) 120 for use in processing signals.

The device 100 may further include a battery 122, which may be used to power the various components of the device 100 (e.g., when the device is disconnected from an external power source). The device 100 may also include a power supply system 123 for managing the power from the battery (or from one or more power ports for receiving external power) to the various components of the device 100. At least a portion of the power supply system 123 may be implemented in one or more power management integrated circuits (power management ICs or PMICs) The power supply system 123 may perform a variety of functions for the device 100 such as DC-to-DC conversion, battery charging, power-source selection, voltage scaling, power sequencing, etc. For example, the power supply system 123 may include one or more power supply circuits, which may include a switched-mode power supply circuit 125. In some aspects, the device 100 may include multiple PMICs for different processing units. Voltage detectors may be implemented at voltage supply paths for the processing units for current throttling, as described in more detail herein.

The various components of the device 100 may be coupled together by a bus system 126, which may include a power bus, a control signal bus, and/or a status signal bus in addition to a data bus. Additionally or alternatively, various combinations of the components of the device 100 may be coupled together by one or more other suitable techniques.

### Example Current Throttling

Certain aspects of the present disclosure are directed towards techniques and apparatus for current throttling (e.g., battery current limiting (BCL)). An electronic device may perform current and voltage measurements at different time scales so that a chipset of the device does not exceed battery capabilities. If a supply voltage (e.g., VPH, an internal device voltage provided from a battery or a charger) suddenly drops to an unacceptable level (e.g., below a threshold), a low latency alarm may be sent to indicate to the chipset (e.g., system on chip (SoC)) to throttle (e.g., reduce current consumption) in an attempt to avoid a system crash.

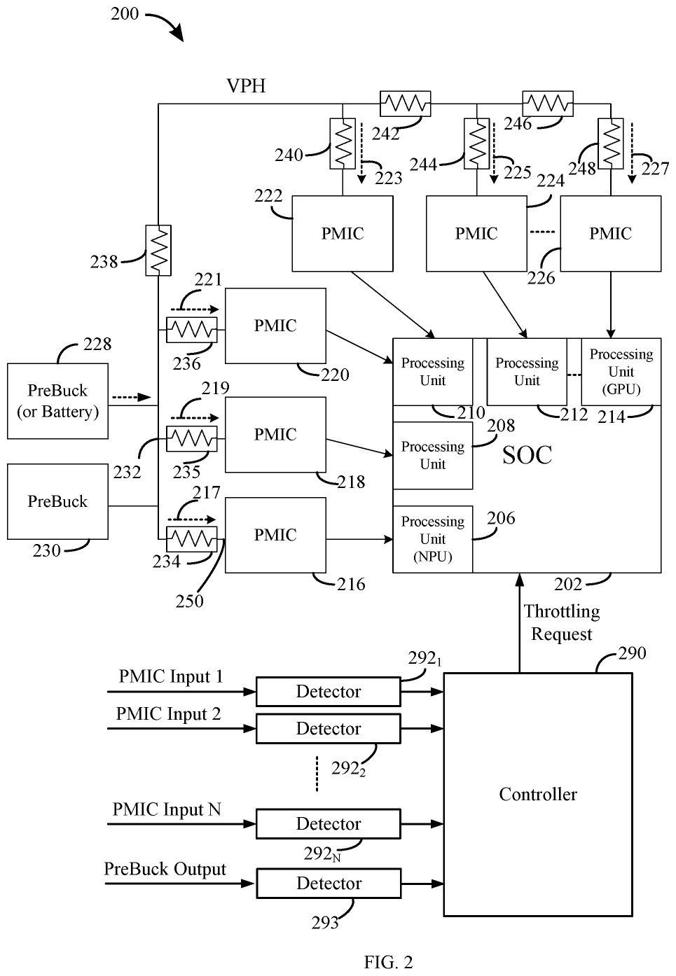

FIG. 2 illustrates an electronic device 200 including multiple PMICs for supplying regulated power to different processing units in a chipset, in accordance with certain aspects of the present disclosure. For example, an SoC 202 may include processing units 206, 208, 210, 212, 214. As shown, the processing unit 214 may be a graphical processing unit (GPU), and the processing unit 206 may be a neural processing unit (NPU).

As shown, the device 200 may include multiple voltage supply paths 217, 219, 221, 223, 225, 227, each path including a PMIC for a respective one of the processing units of the SoC. For example, PMICs 216, 218, 220, 222, 224, 226 may generate separate supply voltages for processing units 206, 208, 210, 212, 214, respectively.

As shown, one or more pre-converter circuits 228, 230 (e.g., buck converter, labeled “PreBuck”) may be used to generate a regulated voltage at node 232, based on which the PMICs may generate supply voltages for respective processing units of the SoC 202. As shown, various impedances (e.g., parasitics) may cause voltage drops between node 232 and the input of each of the PMICs. For example, impedances 234, 235, 236, 240, 244, 248 may be at inputs of the PMICs 216, 218, 220, 222, 224, 226, respectively. Moreover, additional impedances may be considered to be present (e.g., due to the physical routing of the VPH rail from the output(s) of the pre-converter circuits 228, 230 to the various PMICs). For example, impedance 238 may be between node 232 and impedance 240, impedance 242 may be between impedance 238 and impedance 244, and impedance 246 may be between impedance 242 and impedance 248, as shown. The voltage drops across the impedances may cause different amounts of voltage drops for the supply voltages provided to the inputs of different PMICs, resulting in supply voltage variations at the inputs of the PMICs.

Current limiting techniques involve throttling the current consumption of one or more processing units of the SoC based on the detection of an input supply voltage (e.g., at the input of a PMIC) dropping below a threshold in an attempt to avoid a device crash. As used herein, current limiting generally refers to a technique for throttling the power consumption of one or more processors to avoid (or at least reduce the probability of) a device crash. In some cases, current limiting may involve setting an upper limit of the amount of current to be consumed by a processing unit.

The device 200 may include a controller 290, which may include or be coupled to multiple current limiting detectors 292₁ to 292_{N} (collectively referred to herein as “detectors 292”), N being a positive integer. For example, each current limiting detector may perform a voltage measurement at an input of a PMIC (e.g., at PMIC inputs 1 to N, corresponding to inputs of PMICs 216, 218, 220, 222, 224, 226) to determine throttling as described. For example, controller 290 may receive the voltage measurements, based on which a throttling request may be sent to the SoC to throttle the current consumption of one or more processing units (e.g., one or more specific processing units, as indicated by the throttling request).

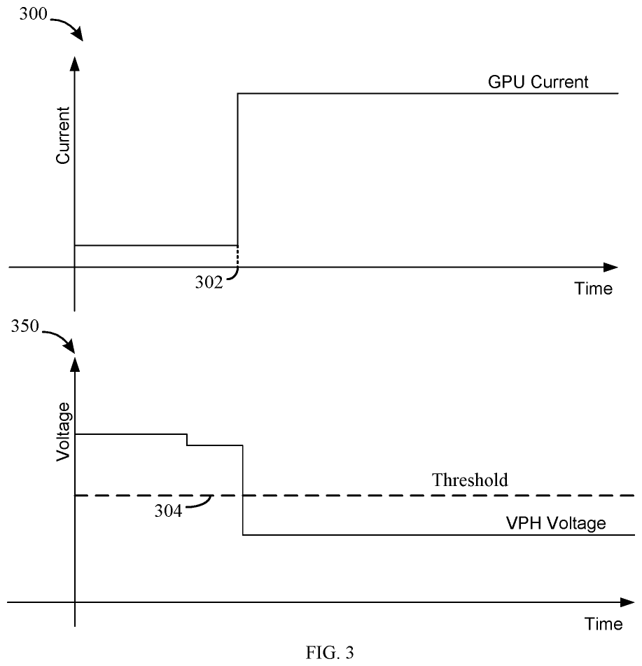

Conventional current limiting techniques (e.g., BCL techniques) perform a voltage measurement at a single sense point (e.g., employ a single current liming detector). For example, a voltage measurement may be performed at the input of a single PMIC (such as PMIC 216) using a single current limiting detector (e.g., voltage measurement circuit). Some legacy devices may use a single sense point due to having lower peak currents, having fewer PMICs, and/or failure to consider imperfect rail and ground planes. Power density is increasing while the area of electronic devices stays the same (or decreases in some cases). Higher current consumption is expected from processing units. For example, some electronic devices have reduced the input supply voltage (e.g., from 3.3 V to 1.8 V); thus, the voltage rail may supply more current to deliver the same amount of power. As a result, using a single sense point may cause various issues, as described in more detail with respect to FIG. 3.

FIG. 3 illustrates a graph 300 showing the current consumption of processing unit 214 (e.g., GPU current consumption) and a graph 350 showing a supply voltage measurement (labeled “VPH Voltage”) at input 250 of PMIC 216 for processing unit 206 (e.g., NPU). As shown, at a certain point in time 302, the GPU current consumption may increase, resulting in the VPH voltage at the input 250 of PMIC 216 to drop below a voltage threshold 304 causing a current limiting alarm (e.g., an alarm that triggers throttling power consumption of one or more processing units). The voltage drop at the input 250 of the PMIC 216 for the NPU may be due to the increased current consumption of the GPU, as shown. Thus, the voltage drop at a node near the PMIC 226 (e.g., at input of PMIC 226) for the GPU may be more than the voltage drop at input of PMIC 216 and may be delayed. Thus, immediate mitigation (e.g., current throttling) may be taken to avoid a device crash. One way to avoid the device crash would be to select a higher current limiting threshold (e.g., compared to the voltage at input of PMIC 226), but this solution may result in over-throttling of processing units in some use cases. Certain aspects of the present disclosure are directed towards using multiple local current limiting alarms. For example, a current limiting detector (e.g., detectors 292) may be implemented for a node near each PMIC input, including the NPU and GPU. The controller 290 may receive voltage measurements performed at an input of each of the PMICs 216, 218, 220, 222, 224, 226, where the received voltage measurements may be used to perform the throttling as described herein. The controller 290 may consider the voltage measurements from the detectors individually or in combination to determine whether (and/or how much) to throttle one or more of the processing units of the SoC 202.

In some aspects, the controller 290 may consider other parameters, such as the output current or voltage of a pre-converter circuit (or a battery). For example, the electronic device 200 may include a detector 293 that may measure a voltage (and/or output current) of the pre-converter circuit 228 (or 230) and may provide the measured voltage and/or current to the controller 290 for consideration of whether (and/or how much) to throttle one or more processing units.

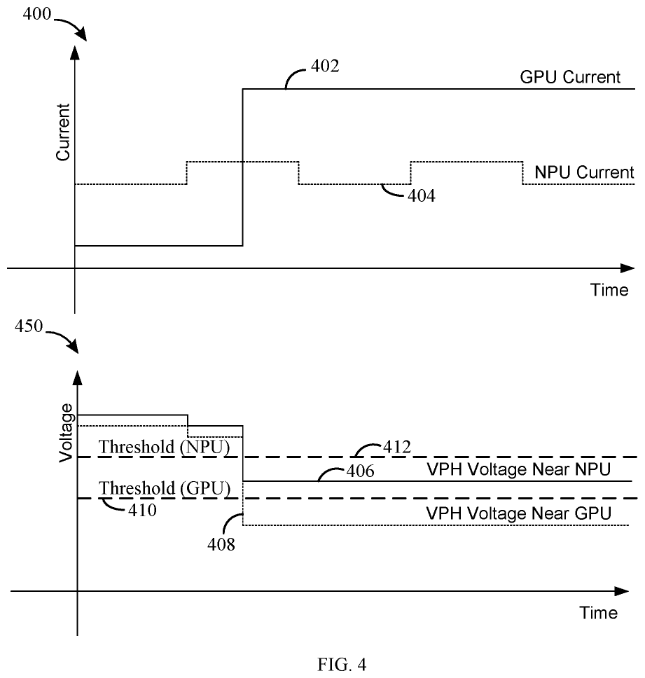

FIG. 4 illustrates a graph 400 showing NPU current consumption 402 and GPU current consumption 404 and a graph 450 showing a supply voltage measurement 406 near the NPU and a supply voltage measurement 408 near the GPU, in accordance with certain aspects of the present disclosure. For example, the voltage measurement 406 may be made at an input of PMIC 216 for the NPU, and the voltage measurement 408 may be made at an input of PMIC 226 for the GPU. As shown, the NPU has a medium load (e.g., medium current consumption), and the GPU steps from light load to high load (e.g., light to high current consumption). The voltage drop at the input of the PMIC 226 for the GPU is large (e.g., drops below threshold 410), and immediate mitigation action (e.g., throttling of the GPU) may be performed to avoid a device crash. The voltage drop near the NPU (e.g., at input of PMIC 216) is not as large. The controller 290 (e.g., based on voltage measurement from the detector for the GPU) may generate a current limiting alarm (e.g., throttling request to the SoC 202) based on the voltage drop at the input of the PMIC 226 for the GPU and can selectively throttle one or more of the processing units of the SoC 202 (e.g., may only throttle the GPU).

The current limiting detectors may be set with different thresholds so that mitigation starts later for some processing units. For instance, the voltage threshold 410 at which mitigation begins for the GPU may be lower than the voltage threshold 412 at which mitigation begins for the NPU. In this manner, the mitigation may be less drastic for some processing units. For example, if the mitigation begins earlier for the NPU sooner than mitigation for the GPU, the eventual mitigation of the GPU may be less drastic (e.g., to reduce current consumption of the GPU, the GPU clock rate may be reduced from 100% to 50%, instead of being reduced to 25%).

Using multiple current limiting detectors provides a faster detection of voltage droop for a specific processing unit, allowing the controller to employ mitigation more quickly. With multiple detectors, an additional margin may not have to be added to the voltage threshold for throttling (e.g., with a single sense point, the voltage threshold may have to be set higher to avoid a device crash as compared to using multiple sense points). Moreover, each detector may be tuned to support a specific power delivery network (PDN) quality (e.g., detector for the GPU may consider the input parasitics of PMIC 226) and allows for more granular mitigation (e.g., can throttle the GPU only as opposed to throttling all processing units).

In some cases, voltage droop detection may be implemented in pre-converter circuits 228, 230. However, not all systems have pre-converter circuits, and detecting the voltage at the pre-converter circuits may result in delay in detecting the voltage drop at the input of PMIC. In some cases, the pre-converter output current (e.g., output currents of pre-converter circuits 228, 230) may be monitored for throttling. However, such an implementation would not account for the PDN (e.g., voltage supply path impedances such as impedance 238) and may be unable to consider factors such as a weak battery or multiple domains (e.g., processing units) having high current consumption at the same time. In some aspects, the throttling techniques described herein may be performed using a combination of measurements, such as the voltage measurement at the input of PMICs, output current of a pre-converter circuit, and/or output voltage of the pre-converter circuit, allowing the controller 290 to identify safe operating states for various cores (e.g., processing units).

### Example Operations for Power Control

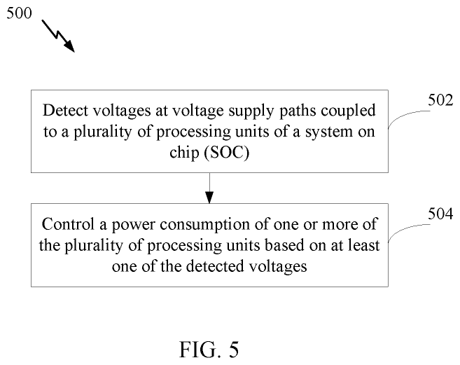

FIG. 5 is a flow diagram illustrating example operations 500 for power control. The operations 500 may be performed by a controller, such as the controller 290 of FIG. 2.

At block 502, the controller detects voltages at voltage supply paths (e.g., paths 217, 219, 221, 223, 225, 227) coupled to a plurality of processing units (e.g., processing units 206, 208, 210, 212, 214, respectively). For certain aspects, the plurality of processing units may be part of a SoC (e.g., SoC 202). At block 504, the controller controls a power consumption of one or more of the plurality of processing units based on at least one of the detected voltages. The voltages may be detected at inputs of a plurality of power supply circuits (e.g., PMICs 216, 218, 220, 222, 224, 226) that are part of the plurality of voltage supply paths, respectively. In some aspects, the controller generation of, via a regulator (e.g., pre-converter circuit 228), a regulated voltage provided to inputs of the plurality of power supply circuits. The power consumption may be controlled further based on at least one of an output current or voltage of the regulator.

In some aspects, the controller may be configured to control the power consumption of one or more of the plurality of processing units based on the detected voltages. In some aspects, controlling the power consumption may include controlling reduction of the power consumption of a specific processing unit of the plurality of processing units based on the detected voltage at the voltage supply path coupled to the specific processing unit being equal to or less than a voltage threshold. In some aspects, controlling the power consumption may include comparing the detected voltages to respective voltage thresholds (e.g., thresholds 410, 412 of FIG. 4). The voltage thresholds may be different.

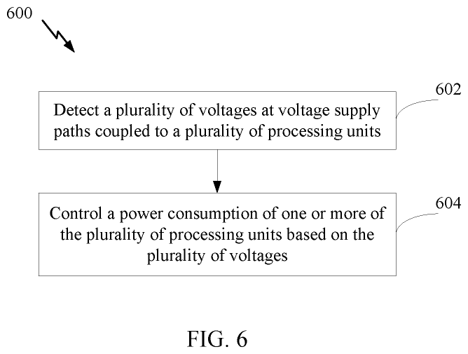

FIG. 6 is a flow diagram illustrating example operations 600 for power control. The operations 600 may be performed by a controller, such as the controller 290 of FIG. 2.

At block 602, the controller detects a plurality of voltages at voltage supply paths coupled to a plurality of processing units. At block 604, the controller controls a power consumption of one or more of the plurality of processing units based on the plurality of voltages. In some aspects, the plurality of voltages are detected at inputs of a plurality of power supply circuits (e.g., PMICs 216, 218, 220, 222, 224, 226) that are part of the plurality of voltage supply paths.

In some aspects, controlling the power consumption may include comparing the plurality of voltages to respective voltage thresholds (e.g., thresholds 410, 412), the voltage thresholds being different. In some aspects, the controller may control generation of, via a regulator, a regulated voltage provided to inputs of the plurality of power supply circuits. The power consumption may be controlled further based on an output current or voltage of the regulator.

### EXAMPLE ASPECTS

Aspect 1: An apparatus for power control, comprising: a system on chip (SoC) having a plurality of processing units, wherein the plurality of processing units are coupled to respective voltage supply paths; voltage detection circuits coupled to the voltage supply paths and configured to detect voltages at the voltage supply paths; and a controller configured to control a power consumption of one or more of the plurality of processing units based on at least one of the detected voltages.
Aspect 2: The apparatus of Aspect 1, wherein the voltage supply paths include a plurality of power supply circuits and wherein the voltage detection circuits are configured to detect the voltages at inputs of the plurality of power supply circuits.
Aspect 3: The apparatus of Aspect 2, wherein the plurality of power supply circuits are parts of power management integrated circuits (PMICs).
Aspect 4: The apparatus of Aspect 2 or 3, further comprising a regulator configured to generate a regulated voltage provided to inputs of the plurality of power supply circuits, wherein the controller is configured to control the power consumption further based on an output current or voltage of the regulator.
Aspect 5: The apparatus according to any of Aspects 1-4, wherein the controller is configured to control the power consumption of one or more of the plurality of processing units based on the detected voltages.
Aspect 6: The apparatus according to any of Aspects 1-5, wherein, to control the power consumption, the controller is configured to reduce the power consumption of a specific processing unit of the plurality of processing units based on the detected voltage at the voltage supply path coupled to the specific processing unit being equal to or less than a voltage threshold.
Aspect 7: The apparatus according to any of Aspects 1-6, wherein, to control the power consumption, the controller is configured to compare the detected voltages to respective voltage thresholds, wherein the voltage thresholds are different.
Aspect 8: An apparatus for power control, comprising: a plurality of processing units coupled to respective voltage supply paths; voltage detection circuits coupled to the voltage supply paths and configured to detect a plurality of voltages at the voltage supply paths; and a controller configured to control a power consumption of one or more of the plurality of processing units based on the plurality of voltages.
Aspect 9: The apparatus of Aspect 8, wherein the voltage supply paths include a plurality of power supply circuits and wherein the voltage detection circuits are configured to detect the plurality of voltages at inputs of the plurality of power supply circuits.
Aspect 10: The apparatus of Aspect 9, wherein the plurality of power supply circuits are parts of power management integrated circuits (PMICs).
Aspect 11: The apparatus of Aspect 9 or 10, further comprising a regulator configured to generate a regulated voltage provided to inputs of the plurality of power supply circuits, wherein the controller is configured to control the power consumption further based on an output current or voltage of the regulator.
Aspect 12: The apparatus according to any of Aspects 8-11, wherein, to control the power consumption, the controller is configured to compare the detected voltages to respective voltage thresholds, wherein the voltage thresholds are different.
Aspect 13: A method for power control, comprising: detecting voltages at voltage supply paths coupled to a plurality of processing units of a system on chip (SoC); and controlling a power consumption of one or more of the plurality of processing units based on at least one of the detected voltages.
Aspect 14: The method of Aspect 13, wherein the voltages are detected at inputs of a plurality of power supply circuits that are part of the voltage supply paths.
Aspect 15: The method of Aspect 14, further comprising generating, via a regulator, a regulated voltage provided to inputs of the plurality of power supply circuits, wherein the power consumption is controlled further based on at least one of an output current or voltage of the regulator.
Aspect 16: The method of Aspect 14 or 15, wherein the plurality of power supply circuits are part of power management integrated circuits (PMICs).
Aspect 17: The method according to any of Aspects 13-16, wherein the power consumption of one or more of the plurality of processing units is controlled based on the detected voltages.
Aspect 18: The method according to any of Aspects 13-17, wherein controlling the power consumption includes reducing the power consumption of a specific processing unit of the plurality of processing units based on the detected voltage at the voltage supply path coupled to the specific processing unit being equal to or less than a voltage threshold.
Aspect 19: The method according to any of Aspects 13-18, wherein controlling the power consumption comprises comparing the detected voltages to respective voltage thresholds, wherein the voltage thresholds are different.
Aspect 20: A method for power control, comprising: detecting a plurality of voltages at voltage supply paths coupled to a plurality of processing units; and controlling a power consumption of one or more of the plurality of processing units based on the plurality of voltages.
Aspect 21: The method of Aspect 20, wherein the plurality of voltages are detected at inputs of a plurality of power supply circuits that are part of the voltage supply paths.
Aspect 22: The method of Aspect 21, further comprising generating, via a regulator, a regulated voltage provided to inputs of the plurality of power supply circuits, and wherein the power consumption is controlled further based on an output current or voltage of the regulator.
Aspect 23: The method according to any of Aspects 20-22, wherein the plurality of power supply circuits are part of power management integrated circuits (PMICs).
Aspect 24: The method according to any of Aspects 20-23, wherein controlling the power consumption includes comparing the plurality of voltages to respective voltage thresholds, wherein the voltage thresholds are different.

### ADDITIONAL CONSIDERATIONS

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation, and details of the methods and apparatus described above without departing from the scope of the claims.

What is claimed is:

1. An apparatus for power control, comprising:
a system on chip (SoC) having a plurality of processing units, wherein the plurality of processing units are coupled to respective voltage supply paths;
voltage detection circuits coupled to the voltage supply paths and configured to detect voltages at the voltage supply paths; and
a controller configured to control a power consumption of one or more of the plurality of processing units based on at least one of the detected voltages.

2. The apparatus of claim 1, wherein the voltage supply paths include a plurality of power supply circuits and wherein the voltage detection circuits are configured to detect the voltages at inputs of the plurality of power supply circuits.

3. The apparatus of claim 2, wherein the plurality of power supply circuits are parts of power management integrated circuits (PMICs).

4. The apparatus of claim 2, further comprising a regulator configured to generate a regulated voltage provided to inputs of the plurality of power supply circuits, wherein the controller is configured to control the power consumption further based on an output current or voltage of the regulator.

5. The apparatus of claim 1, wherein the controller is configured to control the power consumption of one or more of the plurality of processing units based on the detected voltages.

6. The apparatus of claim 1, wherein, to control the power consumption, the controller is configured to reduce the power consumption of a specific processing unit of the plurality of processing units based on the detected voltage at the voltage supply path coupled to the specific processing unit being equal to or less than a voltage threshold.

7. The apparatus of claim 1, wherein, to control the power consumption, the controller is configured to compare the detected voltages to respective voltage thresholds, wherein the voltage thresholds are different.

8. An apparatus for power control, comprising:
a plurality of processing units coupled to respective voltage supply paths;
voltage detection circuits coupled to the voltage supply paths and configured to detect a plurality of voltages at the voltage supply paths; and
a controller configured to control a power consumption of one or more of the plurality of processing units based on the plurality of voltages.

9. The apparatus of claim 8, wherein the voltage supply paths include a plurality of power supply circuits and wherein the voltage detection circuits are configured to detect the plurality of voltages at inputs of the plurality of power supply circuits.

10. The apparatus of claim 9, wherein the plurality of power supply circuits are parts of power management integrated circuits (PMICs).

11. The apparatus of claim 9, further comprising a regulator configured to generate a regulated voltage provided to inputs of the plurality of power supply circuits, wherein the controller is configured to control the power consumption further based on an output current or voltage of the regulator.

12. The apparatus of claim 8, wherein, to control the power consumption, the controller is configured to compare the detected voltages to respective voltage thresholds, wherein the voltage thresholds are different.

13. A method for power control, comprising:
detecting voltages at voltage supply paths coupled to a plurality of processing units of a system on chip (SoC); and
controlling a power consumption of one or more of the plurality of processing units based on at least one of the detected voltages.

14. The method of claim 13, wherein the voltages are detected at inputs of a plurality of power supply circuits that are part of the voltage supply paths.

15. The method of claim 14, further comprising generating, via a regulator, a regulated voltage provided to inputs of the plurality of power supply circuits, wherein the power consumption is controlled further based on at least one of an output current or voltage of the regulator.

16. The method of claim 14, wherein the plurality of power supply circuits are part of power management integrated circuits (PMICs).

17. The method of claim 13, wherein the power consumption of one or more of the plurality of processing units is controlled based on the detected voltages.

18. The method of claim 13, wherein controlling the power consumption includes reducing the power consumption of a specific processing unit of the plurality of processing units based on the detected voltage at the voltage supply path coupled to the specific processing unit being equal to or less than a voltage threshold.

19. The method of claim 13, wherein controlling the power consumption comprises comparing the detected voltages to respective voltage thresholds, wherein the voltage thresholds are different.

20. A method for power control, comprising:
detecting a plurality of voltages at voltage supply paths coupled to a plurality of processing units; and
controlling a power consumption of one or more of the plurality of processing units based on the plurality of voltages.
